(19) United States
(12) Patent Application Publication
(10) Pub. No.: US 2023/0235978 A1
(43) Pub. Date: Jul. 27, 2023

(54) HEAT-DISSIPATING SUBSTRATE WITH COATING STRUCTURE

(71) Applicant: AMULAIRE THERMAL TECHNOLOGY, INC., New Taipei City (TW)

(72) Inventors: MIN-HORNG LIU, New Taipei City (TW); TZE-YANG YEH, New Taipei City (TW)

(21) Appl. No.: 18/131,196

(22) Filed: Apr. 5, 2023

Related U.S. Application Data
(63) Continuation-in-part of application No. 17/203,912, filed on Mar. 17, 2021, now abandoned.

(51) Int. Cl. F28F 19/06; C23C 14/16

(52) U.S. Cl. CPC F28F 19/06; C23C 14/16

(57) ABSTRACT

A heat-dissipating substrate with a coating structure is provided. The heat-dissipating substrate includes at least two layers. A base layer is configured to dissipate heat, and one or more sputtered layers are formed on the base layer. The sputtered layer has a corrosion resistant property, a soldering ability, or a sintering ability. A thickness of the sputtered layer is less than 5 μm.

### CROSS-REFERENCE TO RELATED PATENT APPLICATION

This application is a Continuation-in-Part of the U.S. application Ser. No. 17/203,912 filed on Mar. 17, 2021, and entitled “heat-dissipating substrate with coating structure,” now pending, the entire disclosures of which are incorporated herein by reference.

### FIELD OF THE DISCLOSURE

The present disclosure relates to a heat-dissipating substrate, and more particularly to a heat-dissipating substrate with a coating structure.

### BACKGROUND OF THE DISCLOSURE

A conventional heat-dissipating substrate is shown in FIG. 1. A metal is usually electroplated or sprayed on a surface of the heat-dissipating substrate to improve a corrosion resistance or a solderability of the heat-dissipating substrate. However, an electroplated or sprayed metal layer 20 has a rough surface, a thick thickness, and a poor thickness precision. In addition, thermal cracking can easily occur on the metal layer 20, and the metal layer 20 is restricted by a geometry of the heat-dissipating substrate.

### SUMMARY OF THE DISCLOSURE

In response to the above-referenced technical inadequacies, the present disclosure provides a heat-dissipating substrate with a coating structure.

In one aspect, the present disclosure provides a heat-dissipating substrate with a coating structure, which includes at least two layers. A base layer is configured to dissipate heat, and one or more projections are integrally formed on the base layer. One or more sputtered layers are formed on the projection by sputtering. The sputtered layer has at least one of a corrosion resistant property, a soldering ability, and a sintering ability. A total thickness of the projection is between 2.0 mm and 4.0 mm, a thickness of the sputtered layer is less than 5 μm, and a specific thickness ratio of the projection to the sputtered layer is greater than or equal to 600:1.

In certain embodiments, a total thickness of the base layer is between 2.0 mm and 4.0 mm, the thickness of the sputtered layer is less than 5 um, and a specific thickness ratio of the base layer to the sputtered layer is greater than or equal to 600:1.

In certain embodiments, the projection is a stepped projection having a first sub-projection and a second sub-projection, the first sub-projection is integrally formed on the second sub-projection, and the total thickness of the projection is a sum of a thickness of the first sub-projection and a thickness of the second sub-projection.

In certain embodiments, the heat dissipation layer is made of a copper alloy or an aluminum alloy.

In certain embodiments, the sputtered layer is at least one of a sputtered nickel layer, a sputtered copper layer, a sputtered silver layer, a sputtered nickel alloy layer, a sputtered copper alloy layer and a sputtered silver alloy layer.

In certain embodiments, a thickness precision of the sputtered layer is ±0.2 μm.

In another aspect, the present disclosure provides a heat-dissipating substrate with a coating structure, which includes at least two layers. A base layer is configured to dissipate heat, and the base layer has one or more concavities. One or more sputtered layers are formed on the concavity. The sputtered layer has at least one of a corrosion resistant property, a soldering ability, and a sintering ability. A total thickness of the base layer is between 2.0 mm and 4.0 mm, a thickness of the sputtered layer is less than 5 μm, and a specific thickness ratio of the base layer to the sputtered layer is greater than or equal to 600:1.

In yet another aspect, the present disclosure provides a heat-dissipating substrate with a coating structure, which includes at least two layers. A base layer is configured to dissipate heat, and the base layer has one or more platforms. One or more sputtered layers are formed on the platform. The sputtered layer has at least one of a corrosion resistant property, a soldering ability, and a sintering ability. A total thickness of the base layer is between 2.0 mm and 4.0 mm, a thickness of the sputtered layer is less than 5 μm, and a specific thickness ratio of the base layer to the sputtered layer is greater than or equal to 600:1.

Therefore, the sputtered layer of the heat-dissipating substrate with the coating structure provided by the present disclosure has the thickness of less than 5 μm, and the thickness precision of the sputtered layer 20 can be ±0.2 μm, so that the heat-dissipating substrate provided by the present disclosure includes the coating structure that is extremely thin and that has an extremely high thickness precision. In addition, a thermal cracking is reduced due to less thermal stress between the heat dissipation layer and the sputtered layer of the heat-dissipating substrate provided by the present disclosure, thereby improving a thermal conductivity of the heat-dissipating substrate and increasing a product life thereof. Moreover, the sputtered layer can be formed on the heat dissipation layer having the projection, the concavity or the platform, so that a geometrical restriction is reduced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a side view of a conventional heat-dissipating substrate;

FIG. 2 is a top view of a heat-dissipating substrate according to a first embodiment of the present disclosure;

FIG. 3 is a schematic sectional view taken along line III-III of FIG. 2;

FIG. 4 is a side view of a heat-dissipating substrate according to a second embodiment of the present disclosure;

FIG. 5 is a top view of a heat-dissipating substrate according to a third embodiment of the present disclosure;

FIG. 6 is a schematic sectional view taken along line V-V of FIG. 5;

FIG. 7 is a top view of a heat-dissipating substrate according to a fourth embodiment of the present disclosure; and

FIG. 8 is a schematic sectional view taken along line VII-VII of FIG. 7.

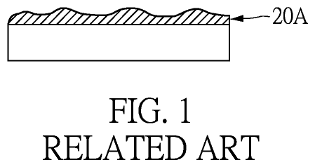

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

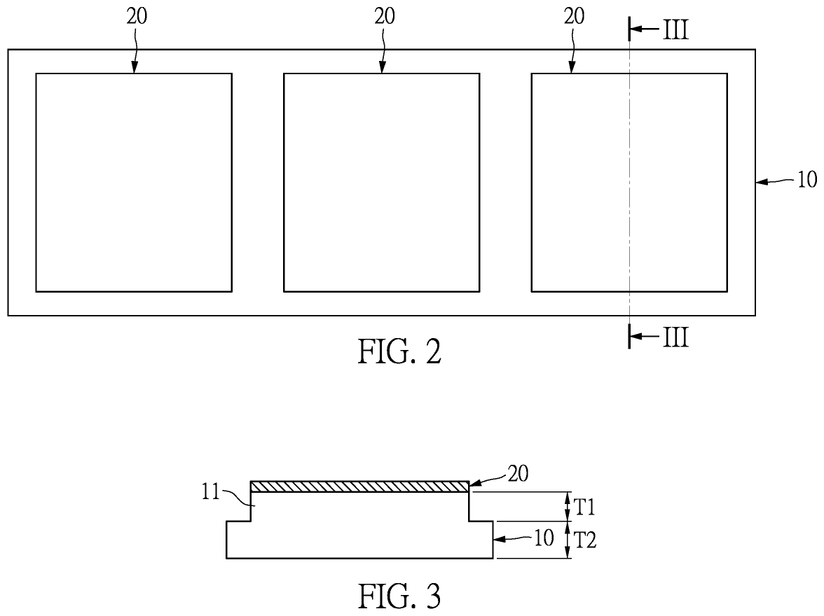

Referring to FIG. 2 and FIG. 3, a first embodiment of the present disclosure provides a heat-dissipating substrate with a coating structure. As shown in the figures, the heat-dissipating substrate with the coating structure according to the first embodiment of the present disclosure includes at least two layers.

One of the at least two layers can be a base layer 10. The base layer 10 can be made of a copper alloy or an aluminum alloy. In the present embodiment, a number of one or more projections 11 on the base layer 10 can be three, but can also be one, two, or three or more. In the present embodiment, the projection 11 is integrally formed on the base layer 10, and the base layer 10 and the projection 11 can together serve as a heat dissipation layer to dissipate heat. Further, the projection 11 of the present embodiment can be integrally formed on the base layer 10 by machining, such as cutting or grinding. In addition, the projection 11 can be integrally formed on the base layer 10 by forging, and can also be integrally formed on the base layer 10 by stamping.

Another one of the at least two layers can be a sputtered layer 20. One or more sputtered layers 20 can be formed on the projection 11. In the present embodiment, when the number of the projections 11 is three, one of the sputtered layers 20 is formed on each of the three projections 11, but two or more of the sputtered layers 20 can also be formed on each of the three projections 11, that is to say, the sputtered layer 20 can have a multi-layer structure.

Further, the sputtered layer 20 can be formed on the projection 11 by sputtering a single metal. The single metal can be nickel, copper or silver. Therefore, the sputtered layer 20 can be a sputtered nickel layer, a sputtered copper layer or a sputtered silver layer, which provides the sputtered layer 20 with a corrosion resistant property, a soldering ability or a sintering ability. In addition, the sputtered copper layer, the sputtered nickel layer and the sputtered silver layer can also be formed in sequence, from bottom to top, on each of the projections 11. Moreover, each of the sputtered layers 20 is extremely thin and has a thickness of less than 5 μm. A thickness precision of the sputtered layer can be ±0.2 μm. Through stability of sputtering, the sputtered layer 20 can have a desired ultra-thin thickness and a high degree of thickness precision.

In another embodiment, the sputtered layer 20 can be formed on the projection 11 by sputtering an alloy metal. The alloy metal can be a nickel alloy, a copper alloy or a silver alloy. Accordingly, the sputtered layer 20 can also be a sputtered nickel alloy layer, a sputtered copper alloy layer or a sputtered silver alloy layer.

In a preferred embodiment, the sputtered layer 20 can be a sputtered silver alloy layer that is configured to be connected with a power module by silver sintering.

Surprisingly it has now been found that when a total thickness T1 of the projection 11 is between 2.0 mm and 4.0 mm and that of the sputtered layer 20 is less than 5 μm, which makes a specific thickness ratio of the projection 11 to the sputtered layer 20 greater than or equal to 600:1, the high internal stress generated by sputtering can be reduced, that is, the stress exerted by the sputtered layer 20 on the projection 11 can be relaxed, and therefore adhesion reliability between the sputtered layer 20 and the projection 11 can be improved.

In addition, in order to maximize adhesion reliability and thermal performance, a total thickness T2 of the base layer 10 is between 2.0 mm and 4.0 mm, the thickness of the sputtered layer 20 is less than 5 um, and a specific thickness ratio of the base layer 10 to the sputtered layer 20 must also be greater than or equal to 600:1.

### Second Embodiment

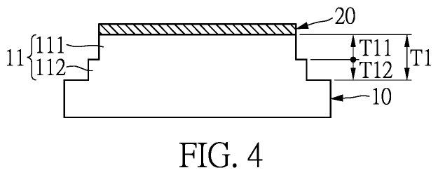

Referring to FIG. 4, a second embodiment of the present disclosure provides a heat-dissipating substrate with a coating structure. In the present embodiment, the projection 11 is integrally formed on the base layer 10, and the base layer 10 and the projection 11 can together serve as a heat dissipation layer to dissipate heat.

One or more sputtered layers 20 can be formed on the projection 11. In the present embodiment, the sputtered layer 20 can be formed on the projection 11 by sputtering. The sputtered layer 20 can be the sputtered nickel layer, the sputtered copper layer, the sputtered silver layer, the sputtered nickel alloy layer, the sputtered copper alloy layer or the sputtered silver alloy layer. The sputtered layer 20 is extremely thin and has the thickness of less than 5 μm. The thickness precision of the sputtered layer 20 can be ±0.2 μm.

In a preferred embodiment, the sputtered layer 20 can be a sputtered silver alloy layer that is configured to be connected with a power module by silver sintering.

It is worth to mention that the projection 11 of the present disclosure is a stepped projection having a first sub-projection 111 and a second sub-projection 112, the first sub-projection 111 is integrally formed on the second sub-projection 112, and the total thickness T1 of the projection 11 is a sum of a thickness T11 of the first sub-projection 111 and a thickness T12 of the second sub-projection 112, thereby achieving an improvement in adhesion reliability and thermal performance.

In a preferred embodiment, the thickness T11 of the first sub-projection T11 can be greater than the thickness T12 of the second sub-projection 112.

### Third Embodiment

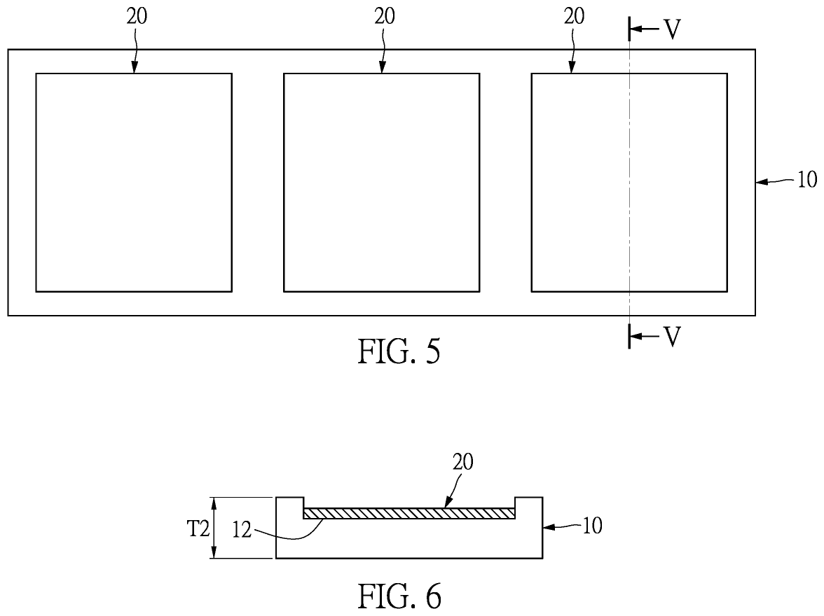

Referring to FIG. 5 to FIG. 6, a third embodiment of the present disclosure provides a heat-dissipating substrate with a coating structure. In the present embodiment, a number of a concavity 12 in a base layer 10 can be three, but can also be one, two, or three or more. The concavity 12 is integrally formed on the base layer 10. The concavity 12 can be integrally formed on the base layer 10 by machining, such as cutting or grinding. In addition, the concavity 12 can be integrally formed on the base layer 10 by forging, and can also be integrally formed on the base layer 10 by stamping.

One or more sputtered layers 20 can be formed on the concavity 12. In the present embodiment, when the number of the concavities 12 is three, one of the sputtered layers 20 is formed on each of the three concavities 12, but two or more of the sputtered layers 20 can also be formed on each of the three concavities 12. The sputtered layer 20 can be formed on the concavity 12 by sputtering. The sputtered layer 20 can be the sputtered nickel layer, the sputtered copper layer, the sputtered silver layer, the sputtered nickel alloy layer, the sputtered copper alloy layer or the sputtered silver alloy layer. In addition, the sputtered copper layer, the sputtered nickel layer and the sputtered silver layer can also be formed in sequence, from bottom to top, on each of the three concavities 12. Moreover, each of the sputtered layers 20 is extremely thin and has the thickness of less than 5 μm. The thickness precision of the sputtered layer 20 can be ±0.2 μm.

In a preferred embodiment, the sputtered layer 20 can be a sputtered silver alloy layer that is configured to be connected with a power module by silver sintering.

In the present embodiment, the total thickness T2 of the base layer 10 is between 2.0 mm and 4.0 mm, the thickness of the sputtered layer 20 is less than 5 μm, and a specific thickness ratio of the base layer 10 to the sputtered layer 20 is greater than or equal to 600:1.

### Fourth Embodiment

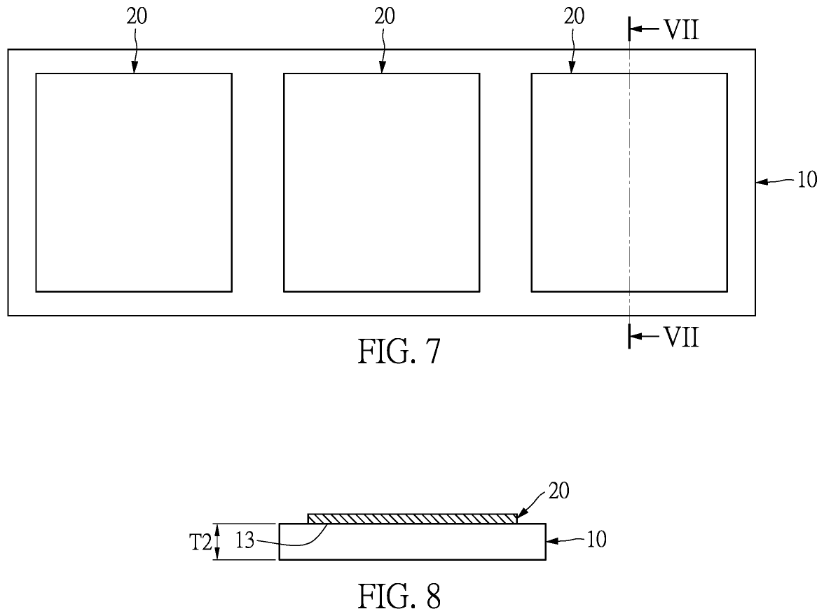

Referring to FIG. 7 to FIG. 8, a fourth embodiment of the present disclosure provides a heat-dissipating substrate with a coating structure. In the present embodiment, a platform 13 is formed on a surface of the base layer 10. The platform 13 is integrally formed on the surface of the base layer 10 by machining, such as grinding.

In addition, one or more sputtered layers 20 can be formed on the platform 13. In the present embodiment, three of the sputtered layers 20 are separately formed on the corresponding platform 13, but one or more of the sputtered layers 20 can also be formed on each of the three sputtered layers 20. The sputtered layer 20 can be formed on the platform 13 by sputtering. The sputtered layer 20 can be the sputtered nickel layer, the sputtered copper layer, the sputtered silver layer, the sputtered nickel alloy layer, the sputtered copper alloy layer or the sputtered silver alloy layer. In addition, the sputtered copper layer, the sputtered nickel layer and the sputtered silver layer can also be formed in sequence, from bottom to top, on each of the three platforms 13. Moreover, each of the sputtered layers 20 is extremely thin and has the thickness of less than 5 μm. The thickness precision of the sputtered layer 20 can be ±0.2 μm.

In a preferred embodiment, the sputtered layer 20 can be a sputtered silver alloy layer that is configured to be connected with a power module by silver sintering.

In the present embodiment, the total thickness T2 of the base layer 10 is between 2.0 mm and 4.0 mm, the thickness of the sputtered layer 20 is less than 5 μm, and a specific thickness ratio of the base layer 10 to the sputtered layer 20 is greater than or equal to 600:1.

### Beneficial Effects of the Embodiments

In conclusion, the sputtered layer 20 of the heat-dissipating substrate with the coating structure provided by the present disclosure has the thickness of less than 5 μm, and the thickness precision of the sputtered layer 20 can be ±0.2 μm, so that the heat-dissipating substrate provided by the present disclosure includes the coating structure that is extremely thin and that has an extremely high thickness precision. In addition, a thermal cracking is reduced due to less thermal stress between the base layer 10 and the sputtered layer 20 of the heat-dissipating substrate provided by the present disclosure, thereby improving a thermal conductivity of the heat-dissipating substrate and increasing a product life thereof. Moreover, the sputtered layer 20 can be formed on the base layer 10 having the projection 11, the concavity 12 or the platform 13, so that a geometrical restriction is reduced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A heat-dissipating substrate with a coating structure, comprising at least two layers; wherein a base layer is configured to dissipate heat, one or more projections are integrally formed on the base layer, one or more sputtered layers are formed on the projection by sputtering, and the sputtered layer has at least one of a corrosion resistant property, a soldering ability, and a sintering ability; wherein a total thickness of the projection is between 2.0 mm and 4.0 mm, a thickness of the sputtered layer is less than 5 μm, and a specific thickness ratio of the projection to the sputtered layer is greater than or equal to 600:1.

2. The heat-dissipating substrate according to claim 1, wherein a total thickness of the base layer is between 2.0 mm and 4.0 mm, the thickness of the sputtered layer is less than 5 um, and a specific thickness ratio of the base layer to the sputtered layer is greater than or equal to 600:1.

3. The heat-dissipating substrate according to claim 1, wherein the projection is a stepped projection having a first sub-projection and a second sub-projection, the first sub-projection is integrally formed on the second sub-projection, and the total thickness of the projection is a sum of a thickness of the first sub-projection and a thickness of the second sub-projection.

4. The heat-dissipating substrate according to claim 1, wherein the heat dissipation layer is made of a copper alloy or an aluminum alloy.

5. The heat-dissipating substrate according to claim 4, wherein the sputtered layer is at least one of a sputtered nickel layer, a sputtered copper layer, a sputtered silver layer, a sputtered nickel alloy layer, a sputtered copper alloy layer, and a sputtered silver alloy layer.

6. The heat-dissipating substrate according to claim 5, wherein a thickness precision of the sputtered layer is ±0.2 μm.

7. A heat-dissipating substrate with a coating structure, comprising at least two layers; wherein a base layer is configured to dissipate heat, the base layer has one or more concavities, one or more sputtered layers are formed on the concavity by sputtering, and the sputtered layer has at least one of a corrosion resistant property, a soldering ability, and a sintering ability; wherein a total thickness of the base layer is between 2.0 mm and 4.0 mm, a thickness of the sputtered layer is less than 5 μm, and a specific thickness ratio of the base layer to the sputtered layer is greater than or equal to 600:1.

8. The heat-dissipating substrate according to claim 7, wherein the heat dissipation layer is made of a copper alloy or an aluminum alloy.

9. The heat-dissipating substrate according to claim 8, wherein the sputtered layer is at least one of a sputtered nickel layer, a sputtered copper layer, a sputtered silver layer, a sputtered nickel alloy layer, a sputtered copper alloy layer, and a sputtered silver alloy layer.

10. The heat-dissipating substrate according to claim 9 wherein a thickness precision of the sputtered layer is ±0.2 μm.

11. A heat-dissipating substrate with a coating structure, comprising at least two layers; wherein a base layer is configured to dissipate heat, the base layer has one or more platforms, one or more sputtered layers are formed on the platform, and the sputtered layer has at least one of a corrosion resistant property, a soldering ability, and a sintering ability; wherein a total thickness of the base layer is between 2.0 mm and 4.0 mm, a thickness of the sputtered layer is less than 5 μm, and a specific thickness ratio of the base layer to the sputtered layer is greater than or equal to 600:1.

12. The heat-dissipating substrate according to claim 11, wherein the heat dissipation layer is made of a copper alloy or an aluminum alloy.

13. The heat-dissipating substrate according to claim 12, wherein the sputtered layer is at least one of a sputtered nickel layer, a sputtered copper layer, a sputtered silver layer, a sputtered nickel alloy layer, a sputtered copper alloy layer, and a sputtered silver alloy layer.

14. The heat-dissipating substrate according to claim 13, wherein a thickness precision of the sputtered layer is ±0.2 μm.
